(19) United States
(12) Patent Application Publication
(10) Pub. No.: US 2015/0237773 A1
(43) Pub. Date: Aug. 20, 2015

(54) COMPONENT MOUNTER

(71) Applicant: Satoru Nishiyama, Nagoya-shi (JP)

(72) Inventor: Satoru Nishiyama, Nagoya-shi (JP)

(73) Assignee: FUJI MACHINE MFG. CO., LTD., Chiryu-shi (JP)

(21) Appl. No.: 14/424,726

(22) PCT Filed: Aug. 31, 2012
(86) PCT No.: PCT/JP2012/072121

§ 371 Date: Feb. 27, 2015

(51) Int. Cl. H05K 13/04

(52) U.S. Cl. CPC H05K 13/0408; H05K 13/0452

(57) ABSTRACT

A component mounter comprising a head placement section on which rotary heads for exchange are placed and a nozzle placement section on which suction nozzles for exchange are placed. A rotary head is exchangeably held on a head holding unit moved by a head moving device, and a suction nozzle is exchangeably held on a rotary head. The component mounter including a control device that controls the operation holding the rotary head on a head placement section and the operation for the suction nozzle on a nozzle placement section to be held by rotary head. By this, automatic exchange of rotary head and automatic exchange of suction nozzle by appropriately selecting them and the time required for exchanging rotary head or suction nozzle can be shortened, thus the operation rate of a component mounter can be improved.

### TECHNICAL FIELD

This present disclosure relates to a component mounter equipped with a head which holds multiple suction nozzles that pick up components.

### BACKGROUND ART

The component mounter disclosed in patent literature 1 (Japanese Patent Publication Number 4546857) comprises a rotary head holding multiple suction nozzles, wherein the rotary head is attached and held to a head holding section of a component mounter using negative pressure suction force in order to be capable of being automatically exchanged according to circumstances such as the type (size, shape, and so on) of components.

On the other hand, the component mounter described in patent literature 2 (Japanese Unexamined Patent Application Publication Number 2006-216627), in order for a suction nozzle being held by a mounting head to be automatically exchanged according to circumstances such as the type (size, shape, and so on) of components, is provided with a nozzle holding mechanism on the mounting head, and suction nozzles are exchangeably held on this nozzle holding mechanism.

### CITATION LIST

### Patent Literature

Patent Literature 1: Japanese Patent Publication Number 4546857

Patent Literature 2: Japanese Unexamined Patent Application Publication Number 2006-216627

### SUMMARY

### Problem to be Solved

With the above current component mounters, because the configuration is such that only either of a rotary head (mounting head) or suction nozzle can be automatically exchanged, depending on the types of components to be mounted on a board, there are cases in which an operator needs to manually exchange a rotary head or exchange a suction nozzle, this was a cause of reducing the operation rate of the component mounter.

Therefore, the object of the present disclosure is to make it possible to perform automatic exchange of a head and automatic exchange of a suction nozzle of a component mounter by appropriately selecting them.

### Means for Solving the Problem

In order to solve the above problem, the present disclosure is directed toward a component mounter equipped with a head holding multiple suction nozzles for picking up components and a head moving device for moving the head, wherein: the head is exchangeably held on a head holding unit which is moved by the head moving device; the suction nozzles are exchangeably held on the head; and the component mounter is equipped with: a head placement section for placing heads for exchange; a nozzle placement section for placing nozzles for exchange; and a control device which controls the head moving device to control the operation for a head on the head placement section to be held by the head holding unit and the operation for a suction nozzle on the nozzle placement section to be held by the head. According to this configuration, it possible to perform automatic exchange of a head and automatic exchange of a suction nozzle of a component mounter by appropriately selecting them and the time required for exchanging a head or suction nozzle can be shortened, thus the operation rate of a component mounter can be improved.

In this case, it is good to have a configuration in which a head rotating mechanism for rotating a head and a nozzle rotating mechanism for correcting the orientation of each component picked up by the suction nozzle by rotating the suction nozzle are assembled on a head holding unit. Thus, a head rotating mechanism and nozzle rotating mechanism can be shared for use for all heads for exchange and it is not required to assemble a head rotating mechanism or nozzle rotating mechanism to a head for exchange, thus enabling downsizing and cost reduction of a head for exchange, and space saving for exchange work.

Also, it is acceptable to have a configuration such that: a nozzle holder for holding a suction nozzle is lowerably held on the head; an engagement protruding section is provided protruding to the side on the upper section of the suction nozzle; an engagement groove with an inverted L shape or inverted J shape into which the engagement protruding section is inserted from below is formed in an engagement cylindrical section which engages the upper section of the suction nozzle in the nozzle holder; and a spring to maintain the state in which the engagement protruding section is engaged with the engagement groove is provided in the nozzle holder. By doing this, a suction nozzle can be held mechanically in a nozzle holder by the engagement of the engagement protruding section at the suction nozzle side and the engagement groove at the nozzle holder side, and positional deviation or dropping of a suction nozzle due to the inertia force can be prevented even if a head is moved at a high speed. However, for the present disclosure, it is also acceptable for a suction nozzle to be held in a nozzle holder using a plunger or plate spring.

Also, it is acceptable to have a configuration such that: a member to be engaged is provided in a connecting section with the head holding unit in a head; an L shape or J shape engaging member which moves between an engagement position engaging with the member to be engaged and an engagement release position released from the engagement is provided on a lower section of the head holding unit; and an air cylinder which is a driving source to move the engaging member between the engagement position and the engagement release position is provided on the head holding unit. By doing this, a head can be held mechanically on the head holding unit by the engagement between an engaging member with an L shape or J shape at the head holding unit side and a member to be engaged at the head side, and positional deviation or dropping of a head due to the inertia force can be prevented even if a head is moved at a high speed. However, for the present disclosure, it is also acceptable for a head to be picked and held on a head holding unit using negative pressure suction force.

### BRIEF DESCRIPTION OF DRAWINGS

FIG. 1 is a perspective view showing an embodiment of the present disclosure, in which a rotary head is shown removed from the head holding unit of the component pickup device.

FIG. 2(a) to (i) are perspective views showing an example of an exchangeable rotary head and an exchangeable suction nozzle.

FIG. 3 is a perspective view showing the R-axis section of a head holding unit.

FIG. 4 is a perspective view of a rotary head.

FIG. 5 is a perspective view showing the engagement holding structure of a suction nozzle.

FIG. 6 is a block diagram showing the configuration of control items of the component mounter.

### DESCRIPTION OF EMBODIMENTS

The following describes a specific embodiment for carrying out the present disclosure. First, the configuration of component pickup device 10 of a component mounter is described.

Multiple nozzle holders 12 are lowerably held in a circumferential direction at predetermined intervals on rotary head 11 (head) of component pickup device 10, and suction nozzles 13 which pick up each component are exchangeably (detachably) engaged and held facing downwards on the lower section of each nozzle holder 12.

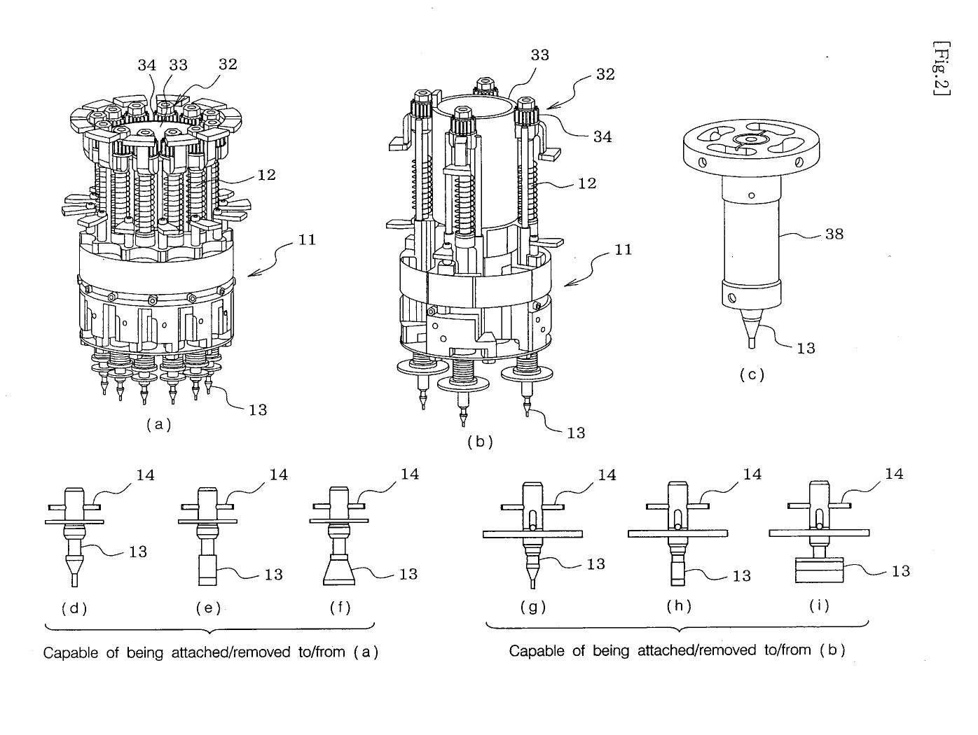

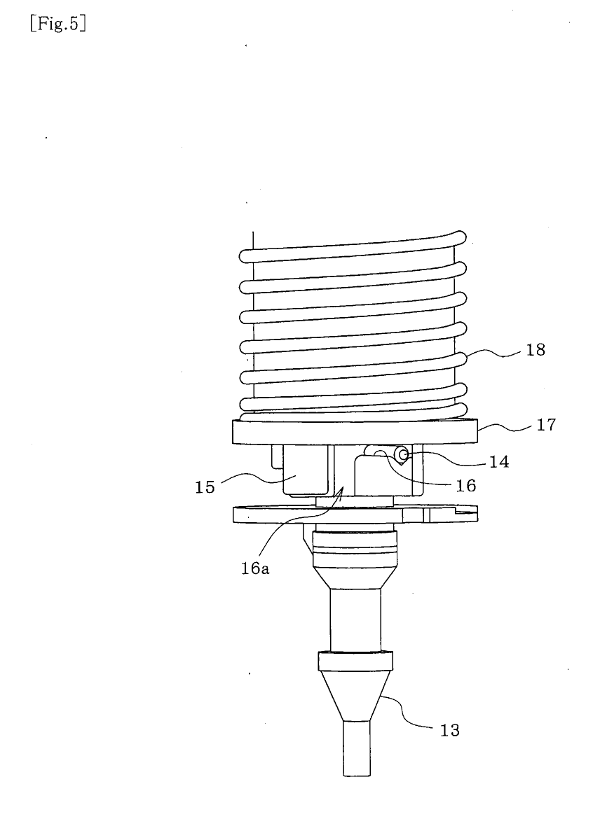

Here, the engagement holding structure of suction nozzle 13 is described using FIG. 2 and FIG. 5. On the upper section of suction nozzle 13, an engagement pin 14 (engagement protruding section) is provided protruding in the diameter direction. In contrast, as shown in FIG. 5, engagement groove 16 (bayonet type engagement groove) with an inverted L shape or inverted J shape is in the engagement cylindrical section 15. An engagement pin 14 is inserted from below into the engagement groove 16. The engagement cylindrical section 15 engages the upper section of suction nozzle 13 in nozzle holder 12. Further, cylindrical pressing member 17 is engaged to be capable of moving up and down in the engagement cylindrical section 15 of nozzle holder 12, and the pressing member 17 is pushed down by spring 18 (spring).

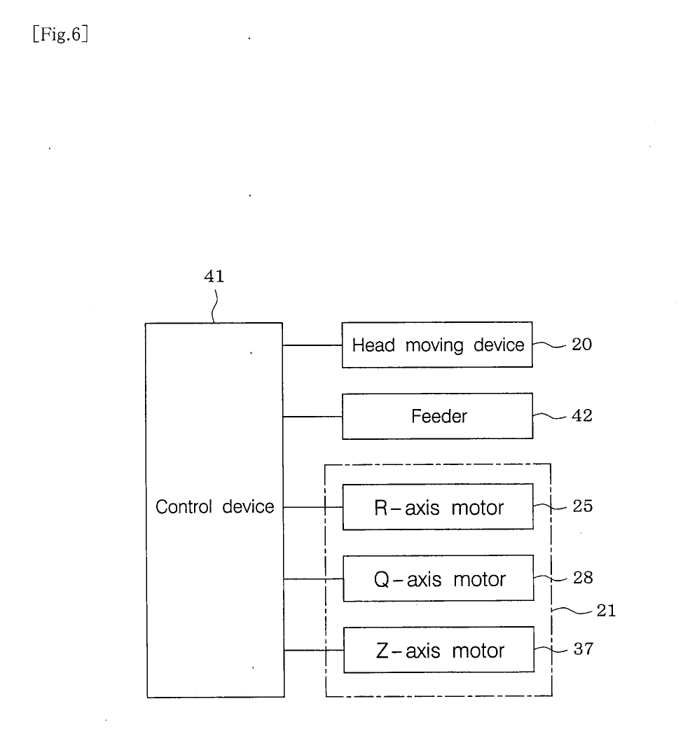

A component mounter is provided with a nozzle placement section (not shown in the figure) on which suction nozzles 13 for exchange are placed. This nozzle placement section is configured such that multiple types of suction nozzles 13 (refer to FIG. 2) can be placed in a state with rotation being stopped (a state in which engagement pin 14 is positioned in a predetermined direction). When attaching suction nozzle 13 placed on this nozzle placement section to nozzle holder 12, first, rotary head 11 is moved above the nozzle placement section by head moving device 20 (refer to FIG. 6), nozzle holder 12 to which suction nozzle 13 is to be attached is positioned directly above the suction nozzle 13, and inlet 16a of engagement groove 16 in engagement cylindrical section 15 of the nozzle holder 12 is entered into a state being positioned at engagement pin 14 of suction nozzle 13. In this state, rotary head 11 is lowered, and after engagement cylindrical section 15 of nozzle holder 12 is pushed into the upper section of suction nozzle 13 and inlet 16a of engagement groove 16 in engagement cylindrical section 15 is inserted into engagement pin 14 of suction nozzle 13, by rotating the nozzle holder 12 in the engagement direction (the end direction of engagement groove 16), engagement pin 14 of suction nozzle 13 is engaged with the V-shaped recess section of engagement groove 16 of the nozzle holder 12. This engaged state is kept by engagement pin 14 being pressed to the V-shaped recess section of engagement groove 16 by pressing member 17 by the spring force of spring 18. When suction nozzle 13 is removed from nozzle holder 12, it is good to remove it in the order reverse to the above, and suction nozzle 13 removed from nozzle holder 12 is placed on the nozzle placement section.

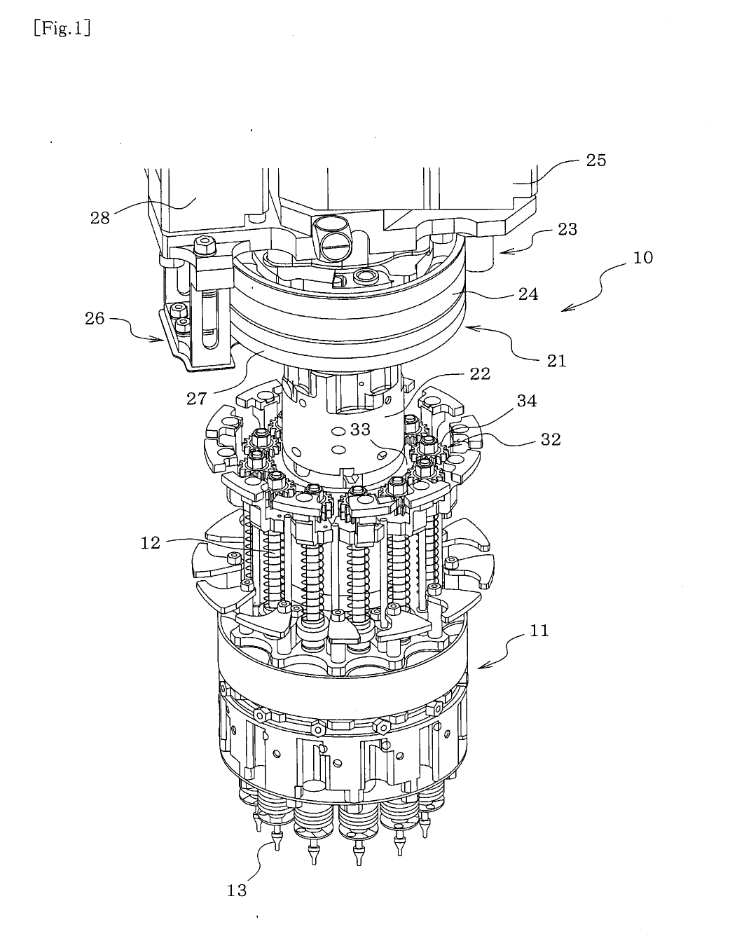

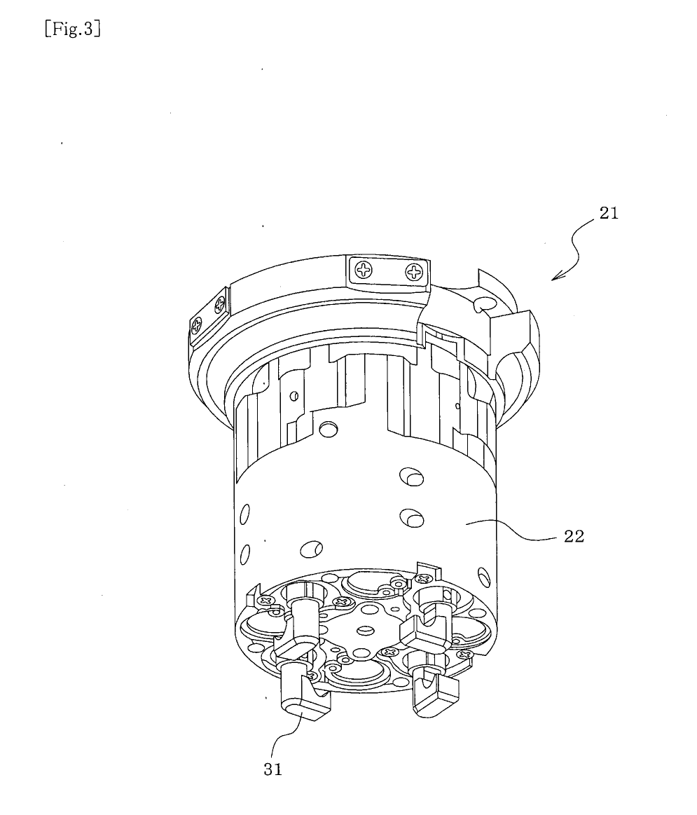

Rotary head 11 is exchangeably (detachably) held on R axis 22 (refer to FIG. 1, FIG. 3) extending downward of head holding unit 21 which is moved by head moving device 20. R-axis driving mechanism 23 (head rotating mechanism) which rotates R axis 22 is assembled on head holding unit 21. R-axis driving mechanism 23 rotates R-axis gear 24 (tooth surface is not shown in the figure) fixed on the upper end of R axis 22 by R-axis motor 25 and rotates rotary head 11 around R axis 22, thus multiple nozzle holders 12 rotate in a circumferential direction of the rotary head 11 integrally with multiple suction nozzles 13.

In R axis 22, Q-axis gear 27 (tooth surface is not shown in the figure) which is a driving source of Q-axis driving mechanism 26 (nozzle rotating mechanism) is rotatably inserted through and the Q-axis gear 27 rotates around R axis 22 by Q-axis motor 28.

As shown in FIG. 3, on the lower section of R axis 22, multiple (for example four) engaging members 31 are provided movably in the up/down direction in order to detachably engage and hold rotary head 11, and close to each engaging member 31, an air cylinder (not shown in the figure) which drives each engaging member 31 in the up/down direction is provided. Each engaging member 31 is respectively formed in an L shape or J shape and arranged at even intervals in a circumferential direction of R axis 22, and the direction of the claw section of each engaging member 31 is arranged so as to be facing in the same direction as the normal rotational direction (or the reverse rotational direction) of R axis 22.

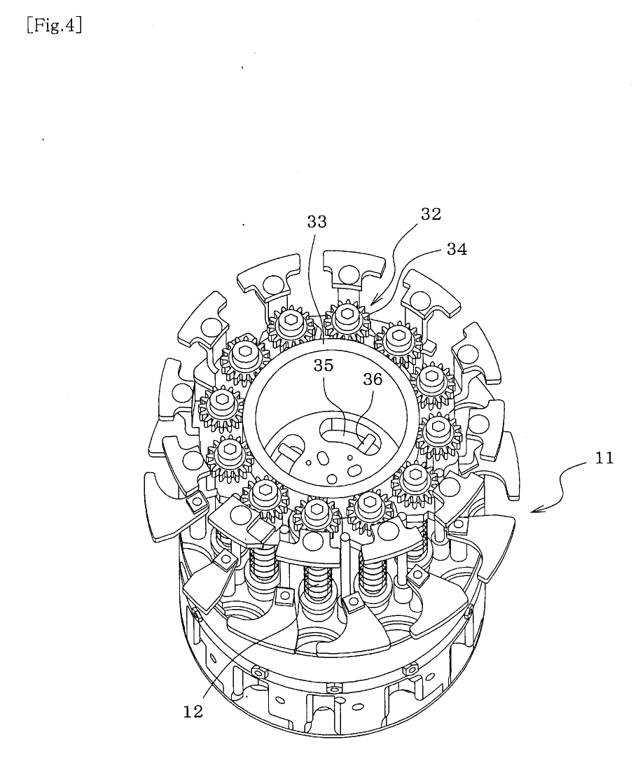

On the other hand, rotary head 11 is provided with nozzle rotating gear mechanism 32 (refer to FIG. 4) for transmitting the rotational power of Q-axis gear 27 to each nozzle holder 12. Nozzle rotating gear mechanism 32 engages cylindrical gear 33 (tooth surface is not shown in the figure) which is rotatably held concentrically at the upper section of rotary head 11 and small gear 34 which is respectively attached to each nozzle holder 12, and by rotating small gear 34 of each nozzle holder 12 by rotating cylindrical gear 33 by Q-axis gear 27 of head holding unit 21, each nozzle holder 12 rotates around the shaft center of each nozzle holder 12 and thus the orientation (angle) of each component picked up by each suction nozzle 13 held by each nozzle holder 12 is corrected.

In order to insert R axis 22 of head holding unit 21 into cylindrical gear 33, the inner diameter of the cylindrical gear 33 is formed slightly larger than the outer diameter of R axis 22. In positions inside cylindrical gear 33 on the upper surface of rotary head 11, multiple elongated holes 35 for inserting through each engaging member 31 of R axis 22 are formed at even intervals in a circumferential direction, and on one side of each elongated hole 35, pin to be engaged 36 (member to be engaged) which is engaged by the claw section of engaging member 31 is fixedly penetrating in the radial direction of rotary head 11. To the side of pin to be engaged 36 of each elongated hole 35, a gap is maintained so that engaging member 31 can pass by in the up/down direction.

The component mounter is provided with a head placement section (not shown in the figure) on which rotary head 11 for exchange is placed. This head placement section is configured such that multiple types of rotary heads 11 can be placed. When attaching rotary head 11 placed on this head placement section to head holding unit 21, R axis 22 of head holding unit 21 is inserted into cylindrical gear 33 and each engaging member 31 of R axis 22 is inserted into each elongated hole 35 of rotary head 11, and each engaging member 31 is pulled up and held while each engaging member 31 is engaged with pin to be engaged 36 in each elongated hole 35 by rotating R axis 22 by the rotation of R-axis gear 24. On head holding unit 21, various different types of rotary heads 11 [refer to FIG. 2(a), (b)] can be held and mounting head for single nozzle 38 [refer to FIG. 2(c)] can be also held.

Z-axis driving mechanism (not shown in the figure) using Z-axis motor 37 (refer to FIG. 6) as a driving source is assembled on head holding unit 21 in addition to R-axis driving mechanism 23 and Q-axis driving mechanism 26, and the configuration is such that nozzle holder 12 is lowered at the predetermined stopping position of the rotational path of nozzle holder 12 by the Z-axis driving mechanism.

Head holding unit 21 of component pickup device 10 configured as above moves in the XYZ directions by being held on head moving device 20 of a component mounter. Control device 41 (refer to FIG. 6) of the component mounter, according to a production program, controls head moving device 20, R-axis motor 25 of head holding unit 21, Q-axis motor 28, and Z-axis motor 37, and as well as controlling the operation for a component supplied from feeder 42 set in a component mounter to be picked up and mounted on a circuit board, controls the operation for rotary head 11 on a head placement section to be held by head holding unit 21 and the operation for suction nozzle 13 on a nozzle placement section to be held by rotary head 11.

Because the component mounter of the present embodiment described above comprises a head placement section on which rotary heads 11 for exchange are placed and a nozzle placement section on which suction nozzles 13 for exchange are placed, and is configured such that rotary head 11 is exchangeably held on R axis 22 of head holding unit 21 moved by head moving device 20 and suction nozzle 13 is exchangeably held on nozzle holder 12 of rotary head 11, it is possible to perform automatic exchange of rotary head 11 and automatic exchange of suction nozzle 13 by appropriately selecting them and the time required for exchanging rotary head 11 or suction nozzle 13 can be shortened, thus the operation rate of a component mounter can be improved.

Also, in the present embodiment, because the configuration is such that R-axis driving mechanism 23 (head rotating mechanism) for rotating rotary head 11 and Q-axis driving mechanism 26 (nozzle rotating mechanism) for correcting the orientation of a component picked up by suction nozzle 13 by rotating suction nozzle 13 are assembled on head holding unit 21 which holds rotary head 11 exchangeably, R-axis driving mechanism 23 and Q-axis driving mechanism 26 can be shared for use for all rotary heads 11 for exchange and it is not required to assemble R-axis driving mechanism 23 or Q-axis driving mechanism 26 to rotary head 11 for exchange, thus enabling downsizing and cost reduction of rotary head 11 for exchange, and space saving for exchange work.

Further, in the present embodiment, because suction nozzle 13 is held mechanically in nozzle holder 12 by the engagement of engagement pin 14 at the suction nozzle 13 side and engagement groove 16 at the nozzle holder 12 side, positional deviation or dropping of suction nozzle 13 due to the inertia force can be prevented even if rotary head 11 is moved at a high speed. However, for the present disclosure, it is also acceptable for suction nozzle 13 to be held in nozzle holder 12 using a plunger or plate spring.

Also, because rotary head 11 is held mechanically in head holding unit 21 by the engagement of engaging member 31 at the head holding unit 21 side and pin to be engaged 36 at the rotary head 11 side, positional deviation or dropping of rotary head 11 due to the inertia force can be prevented even if rotary head 11 is moved at a high speed. However, for the present disclosure, it is also acceptable for rotary head 11 to be picked and held on head holding unit 21 using negative pressure suction force.

Furthermore, the present disclosure is not limited to the above embodiment, and various embodiments with changes that do not extend beyond the scope of the present disclosure are possible such as it is acceptable to appropriately change, for example, the configuration of rotary head 11 engaged and held in head holding unit 21, or the configuration of suction nozzle 13 engaged and held in nozzle holder 12, or to have a configuration such that a head which does not rotate is held by a head holding unit.

### REFERENCE NUMBER LIST

10: Component pickup device

11: Rotary head (head)

12: Nozzle holder

13: Suction nozzle

14: Engagement pin (engagement protruding section)

15: Engagement cylindrical section

16: Engagement groove

17: Pressing member

18: Spring

20: Head moving device

21: Head holding unit

22: R axis

23: R-axis driving mechanism (head rotating mechanism)

24: R-axis gear

25: R-axis motor

26: Q-axis driving mechanism (nozzle rotating mechanism)

27: Q-axis gear

28: Q-axis motor

31: Engaging member

32: Nozzle rotating gear mechanism

33: Cylindrical gear

34: Small gear

35: Elongated hole

36: Pin to be engaged (member to be engaged)

37: Z-axis motor

38: Mounting head

41: Control device

42: Feeder

1. A component mounter, comprising:
a plurality of heads, each respective head holding multiple suction nozzles to pick up components, the suction nozzles being exchangeable held on the respective head and the respective head being exchangeably held on a head holding unit;
a head moving device that moves the head holding unit;
a head placement section that places heads for exchange;
a nozzle placement section that places nozzles for exchange; and
a control device which controls the head moving device to control operation for a head on the head placement section to be held by the head holding unit; and controls the operation for a suction nozzle on the nozzle placement section to be held by the head.

2. The component mounter according to claim 1, wherein the head holding unit includes a head rotating mechanism that rotates the head and a nozzle rotating mechanism that corrects an orientation of each component picked up by the suction nozzle by rotating the suction nozzle.

3. The component mounter according to claim 1 wherein a nozzle holder that holds the suction nozzle is lowerably held on the head;
an engagement protruding section protruding protrudes to the side on the an upper section of the suction nozzle;
an engagement groove with an inverted L shape or inverted J shape into which the engagement protruding section is inserted from below is in an engagement cylindrical section which engages the upper section of the suction nozzle in the nozzle holder; and
a spring to maintain a state in which the engagement protruding section is engaged with the engagement groove is in the nozzle holder.

4. The component mounter according to claim 1, wherein
a member to be engaged is in a connecting section with the head holding unit in the head;
an L shape or J shape engaging member which moves between an engagement position engaging with the member to be engaged and an engagement release position released from the engagement is on a lower section of the head holding unit; and
an air cylinder which is a driving source to move the engaging member between the engagement position and the engagement release position is on the head holding unit.
